(19) United States
(12) Patent Application Publication
(10) Pub. No.: US 2007/0279272 A1
(43) Pub. Date: Dec. 6, 2007

(54) Semiconductor device and method for manufacturing the same

(75) Inventors: Satoshi Sobue, Nukata-gun (JP); Hiroyuki Ban, Hazu-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/806,326

(22) Filed: May 31, 2007

(30) Foreign Application Priority Data
Jun. 5, 2006 (JP) 2006-155933

(51) Int. Cl. H03M 1/78

(52) U.S. Cl. 341/154

(57) ABSTRACT

A semiconductor device includes a semiconductor substrate, a first wire disposed on the semiconductor substrate, an first insulating layer disposed on the semiconductor substrate and the wire, a first thin film resistor having a first resistance within a predetermined error range, and a second thin film resistor having a second resistance which is allowable to be out of the predetermined error range. A surface of the first insulating layer includes a first area and a second area, in which the second area is located adjacent to the first wire. The first thin film resistor is disposed in the first area, and the second thin film resistor is disposed in the second area.

### CROSS REFERENCE TO RELATED APPLICATION

This application is based on Japanese Patent Application No. 2006-155933 filed on Jun. 5, 2006, the content of which is incorporated herein by reference in its entirety.

### BACKGROUND OF THE INVENTION

1. Field of the Invention

The present invention relates to a semiconductor device having a thin film resistor, and a method for manufacturing the same.

2. Description of the Related Art

Conventionally, in a semiconductor device having a resistance element formed on a semiconductor substrate, a semiconductor integrated circuit is formed by a method, for example, including a step of forming an insulating layer on a semiconductor substrate, a step of forming a thin film resistor on the surface of the insulating layer, a step of forming an arranged plurality of thin film resistors having predetermined shapes by the photolithographic method and an etching, and a step of forming a wire.

For example, JP-A-2005-259802 discloses a semiconductor device in which thin film resistors are formed by a process shown in FIGS. 4A-4D.

At first, as shown in FIG. 4A, a first insulating layer 113 is formed on a semiconductor substrate 111, and a wire 114 is patterned and formed on the first insulating layer 113. Then, a second insulating layer 115 is formed on the wire 114 and the first insulating layer 113, and a resistor layer 122 is formed on the second insulating layer 115.

Next, as shown in FIG. 4B, the resistor layer 122 is coated with a photoresist 130, and the photoresist 130 is exposed and developed to form a pattern. Then, as shown in FIG. 4C, the resistor layer 122 is etched with patterned photoresists 130a-130e as masks. As a result, as shown in FIG. 4D, thin film resistors 116a-116e are formed on the second insulating layer 115.

In the vicinity of the wire 114, a thickness of the photoresist 130 becomes uneven due to a step height H1 between the wire 114 and the second insulating layer 115. Specifically, the photoresist 130 is formed to be thicker towards the wire 114, and the photoresist 130a on a side of the wire 114 becomes thicker than the photoresists 130b-130e.

When the thickness of the photoresist 130 is changed, wire widths of the thin film resistors are changed in accordance with taper angles. Therefore, a wire width Wa of the thin film resistor 116a on a side of the wire 114 becomes wider than a wire width Wb of the thin film resistor 116b which is formed into a size within a predetermined error range. Thus, the thin film resistor 116a may be formed to be out of a predetermined dimensional accuracy, and may have a resistance out of a predetermined error range. These problems can be prevented by forming the thin film resistor 116a in an area in which the thickness of the photoresist 130 is approximately even. However, in this case, an interval L1 between the wire 114 and the thin film resistor 116a is required to be approximately 100 μm, and a chip size becomes large due to the intervals. Furthermore, when another resistor such as a pull-up resistor is formed on the same substrate apart from these thin film resistors, an area occupied by the various resistors becomes large. Therefore, the chip size may be large.

### SUMMARY OF THE INVENTION

In view of the foregoing problems, it is an object of the present invention to provide a semiconductor device in which a resistance of a thin film resistor is within a predetermined error range and a chip size is small. And another object of the invention is to provide a method for manufacturing the same.

According to a first aspect of the invention, a semiconductor device includes a semiconductor substrate, a first wire disposed on the semiconductor substrate, an first insulating layer disposed on the semiconductor substrate and the first wire, a first thin film resistor having a first resistance within a predetermined error range, and a second thin film resistor having a second resistance which is allowable to be out of the predetermined error range. A surface of the first insulating layer includes a first area and a second area, in which the second area is located adjacent to the first wire. The first thin film resistor is disposed in the first area, and the second thin film resistor is disposed in the second area.

In the semiconductor device according to the first aspect of the invention, the thin film resistor has the resistance within the predetermined error range, and the chip size is small.

According to a second aspect of the invention, a semiconductor device includes a semiconductor substrate, a first wire disposed on the semiconductor substrate, a first insulating layer disposed on the semiconductor substrate and the first wire, a first thin film resistor having a first resistance within a first error range, and a second thin film resistor having a second resistance within a second error range. The first error range is smaller than the second error range. A surface of the first insulating layer includes a first area and a second area, in which the second area is located adjacent to the first wire. The first thin film resistor is disposed in the first area, and the second thin film resistor is disposed in the second area.

In the semiconductor device according to the second aspect of the invention, the thin film resistor has the resistance within the predetermined error range, and the chip size is small.

According to a third aspect of the invention, a method for manufacturing a semiconductor device is provided. The method includes: a step of forming a first wire on a semiconductor substrate; a step of forming a first insulating layer on the semiconductor substrate and the first wire; a step of dividing a surface of the first insulating layer into a first area and a second area, in which the second area is located adjacent to the first wire; a step of forming a first thin film resistor having a first resistance within a first error range in the first area; and a step of forming a second thin film resistor having a second resistance within a second error range in the second area. The first error range is smaller than the second error range. The first area and the second area is divided in such a manner that when a photoresist covers a resistor material film arranged on the surface of the first insulating layer, a thickness of the photoresist is approximately even in the first area, and the thickness of the photoresist is uneven in the second area due to a step height between the first wire and the surface of the semiconductor substrate.

According to the method of the third aspect of the invention, the semiconductor device, in which the thin film resistor has the resistance within the predetermined error range, and the chip size is small, can be manufactured.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1A is a plan view showing a semiconductor device according to an embodiment of the invention, and FIG. 1B is a cross-sectional view of the semiconductor device taken along wire IB-IB in FIG. 1A;

FIGS. 2A to 2E are diagrams showing a manufacturing process of the semiconductor device according to the embodiment;

FIGS. 3A and 3B are plan views showing semiconductor devices according to modifications of the invention; and

FIGS. 4A to 4D are diagrams showing a manufacturing process of a semiconductor device according to a prior art.

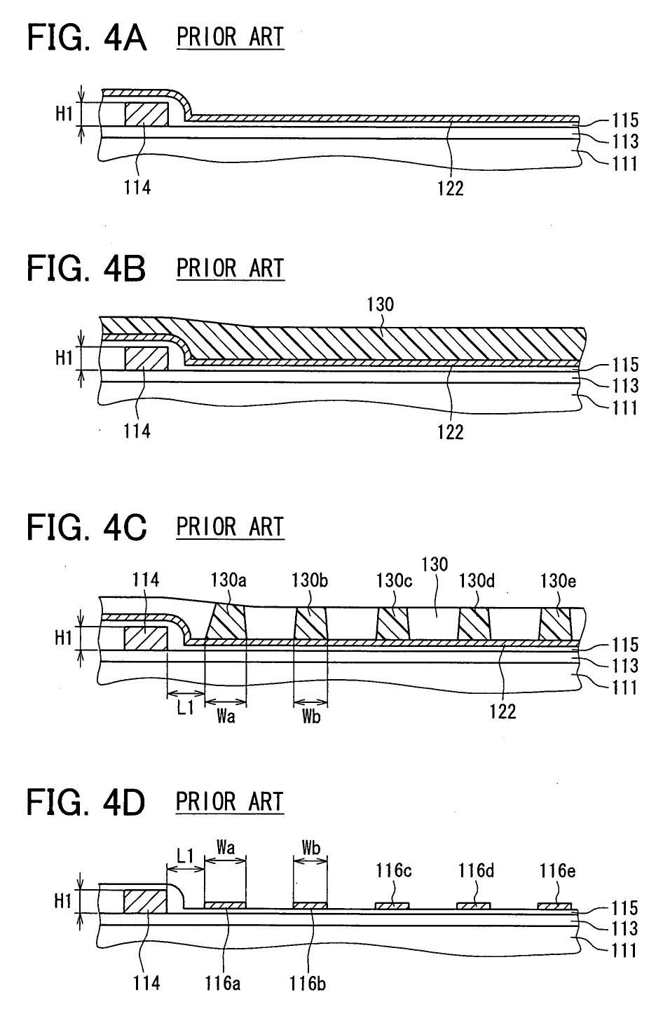

### DETAILED DESCRIPTION OF THE PREFERRED EMBODIMENTS

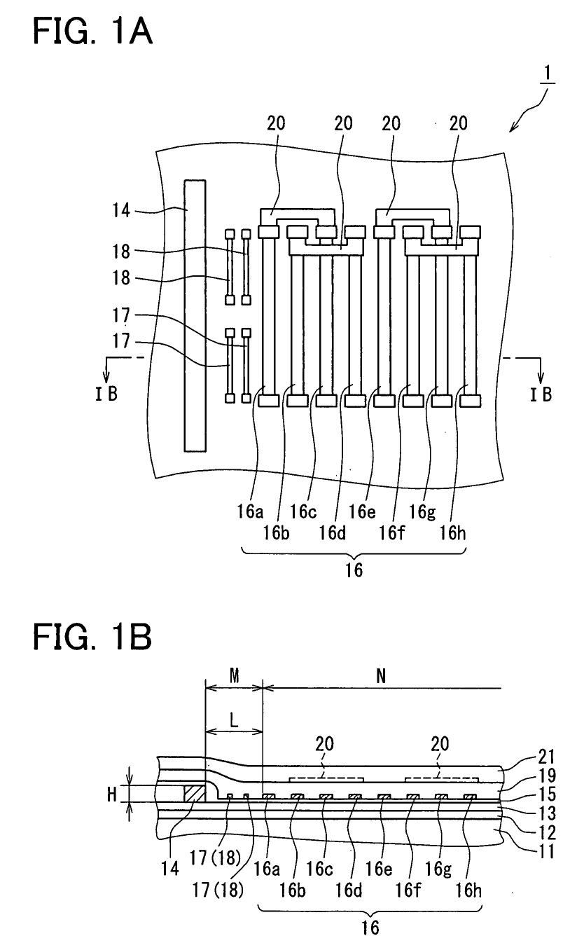

As shown in FIGS. 1A and 1B, in the semiconductor device according to an embodiment of the invention, a field oxide layer 12 and a BPSG (Boron Phosphorous Silicate Glass) layer 13 are formed in this order on a semiconductor substrate 11 in which semiconductor elements (not shown) are formed. A field oxide layer 12 is formed for electrically isolating the semiconductor elements, and the BPSG layer 13 is a planarization interlayer material. On the surface of the BPSG layer 13, a first Al wire 14, which is a metal wire at a lower layer, is formed into a band shape.

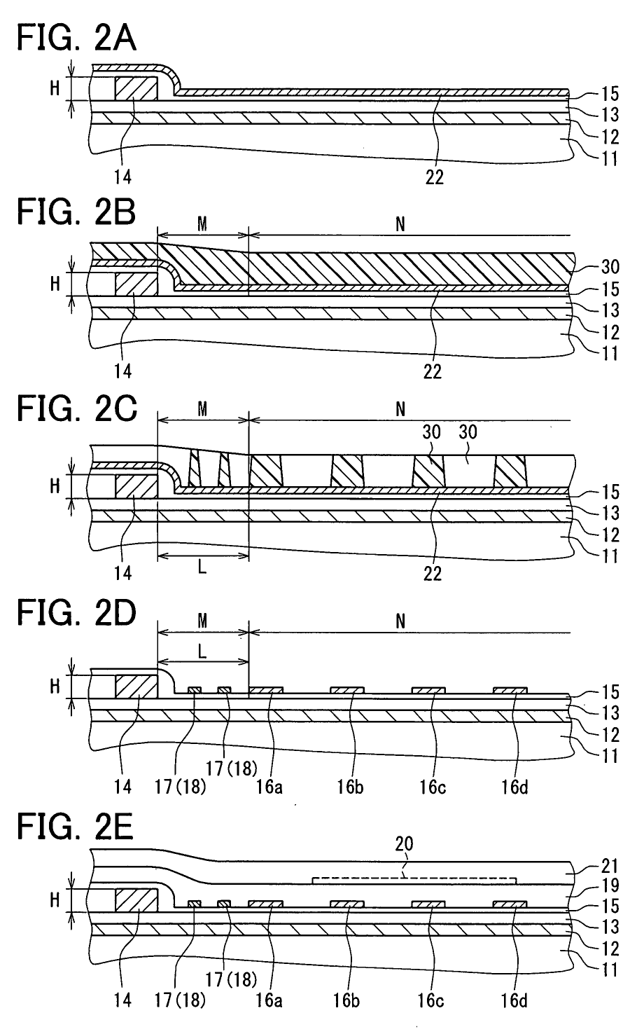

A first TEOS (tetraethoxysilane) layer 15, which is an interlayer dielectric layer, is formed for covering the first Al wire 14. A surface of the first TEOS layer is divided into two areas, i.e., a first area N and a second area M. The second area M is located adjacent to the first Al wire 14. As shown in FIGS. 2B and 2C, the areas are divided in such a manner that when a photoresist 30 covers a thin film resistor material 22 formed on the surface of the first TEOS layer 15, a thickness of the photoresist 30 is approximately even in the first area N, and the thickness of the photoresist 30 is uneven in the second area M, due to a step height H between the first Al wire 14 and the BPSG layer 13.

On the first TEOS layer 15, stripe-shaped thin film resistors 16 are formed in the first area N at a predetermined distance L from the first Al wire 14. The thin film resistors 16 are located to be parallel to the first Al wire 14, and are arranged in parallel to each other at even intervals. For example, eight thin film resistors 16a-16h, which are respectively formed to be 8 μm in wire width and 160 μm in length, are arranged at intervals of 7 μm. The thin film resistors 16a-16h are made by a CrSi layer having a high resistance and a good temperature property. Because the thickness of the photoresist 30 is formed into approximately even in the first area N, the thin film resistors 16 can have high dimensional accuracy. Therefore, the thin film resistors 16 having resistances in the predetermined error range can be provided.

In the second area M, resistance elements, which are not required high accuracy compared with the thin film resistors 16, e.g., pull-up resistors 17 and current-limit resistors 18, are located. The current-limit resistors 18 limit a current provided to a LED. Because the thickness of the photoresist 30 is uneven in the second area M, it is difficult to form a resistor having a resistance in the predetermined error range. However, the pull-up resistors 17 and the current-limit resistors 18 are not required high accuracy compared with the thin film resistor 16, and may be out of the predetermined error range. Therefore, the pull-up resistors 17 and the current-limit resistors 18 can be formed in the second area M. A second TEOS layer 19, which is an interlayer dielectric layer, is formed for covering the thin film resistors 16, the pull-up resistors 17, and the current-limit resistors 18, for example.

On a surface of the second TEOS layer 19, second Al wires 20, which are metal wires at an upper layer, are formed. For example, each of the second Al wires 20 is connected with two of the thin film resistors 16a-16h as a set. The thin film resistors 16 connected with the second Al wires 20 are used as resistors for forming an integrated circuit with the semiconductor elements. For example, one pair of the thin film resistors 16 selected from the connected sets of the thin film resistors 16 is used as a load resistor of a bipolar transistor differential amplifier circuit. In this case, a resistance ratio of one pair of the thin film resistors 16 is required to be a predetermined resistance ratio.

In the embodiment, the thin film resistors 16 having different distances from the first Al wire 14 are alternately connected by the second Al wires 20 in such a manner that the thin film resistor 16a is connected with the thin film resistor 16c, and the thin film resistor 16b is connected with the thin film resistor 16d, and the one pair of the resistors is selected from the connected sets of the resistors 16. For example, the one pair of the resistors is formed by the set of the thin film resistor 16a and the thin film resistor 16c and the set of the thin film resistor 16b and the thin film resistor 16d. Thus, locations of four thin film resistors 16a to 16h forming each set are homogeneous with respect to a location of the first Al wire 14. Therefore, variation in the resistances of the sets of each pair of the thin film resistors 16 can be small, and the resistance ratio can be exactly set to be a predetermined vale. Then, a protection layer 21 covers surfaces of the second Al wire 20 and the second TEOS layer 19.

As described above, in the semiconductor device 1 according to the embodiment, the surface of the first TEOS layer 15 located at an upper layer from the fist Al wire 14 is divided into the first area N and the second area M. The second area M is located adjacent to the first Al wire 14 and the thickness of the photoresist 30 in the second area M is uneven. In the first area N, the thickness of the photoresist 30 is approximately even. The thin film resistors 16 having the resistances within the predetermined error range are formed in the first area N. In the second area M, the resistors having resistances which are allowable to be out of the predetermined error range, e.g., the pull-up resistors 17 and the current-limit resistors 18, can be formed. In a conventional semiconductor device, the pull-up resistors 17 and the current-limit resistors 18 are located at another space. Therefore, in the semiconductor device according to the embodiment, a chip size can be smaller compared with that of the conventional semiconductor device.

A layer material for forming the thin film resistors 16 is not limited to CrSi, and a resistor material such as PolySi, MoSi, and TiN can be used as the layer material. Furthermore, a shape and a number of the thin film resistors 16 are not limited to those of the embodiment, and the thin film resistor 16 may be formed into a wide square-shaped area.

Next, a manufacturing process of the above-described semiconductor device 1 will be described with reference to FIGS. 2A-2E. In FIGS. 2A-2E, an area in which the thin film resistors 16a-16d are formed is enlarged.

At first, as shown in FIG. 2A, the semiconductor substrate 11, in which the semiconductor elements (not shown) and the field oxide layer 12 are formed by a well-known process, is provided. The BPSG layer 13 is formed on the field oxide layer 12, and the band-shaped first Al wire is patterned and formed on the surface of the BPSG layer 13. Then, the first TEOS layer 15 is formed on the surface of the BPSG layer 13 and the first Al wire 14, and the resistor layer 22 such as the CrSi layer is formed on the surface of the first TEOS layer 15 by a method such as sputtering.

Next, as shown in FIG. 2B, the photoresist 30 is coated on the surface of the resistor layer 22. Then, the surface of the first TEOS layer 15 is divided into a first area N and the second area M, in which the second area M is located adjacent to the first Al wire 14. The areas N and M are divided in such a manner that and the thickness of the photoresist 30 is approximately even in the first area N, and the thickness of the photoresist 30 is uneven in the second area M due to the step height H between the first Al wire 14 and the surface of the BPSG layer 13.

Next, as shown in FIG. 2C, a predetermined mask pattern is formed so that the pull-up resistors 17 and the current-limit resistors 18 are formed in the second area M, and the thin film resistors 16 (16a-16d) are formed in the first area N.

Next, as shown in FIG. 2D, the resistor layer 22 is etched with the photoresist 30 as the mask for forming the thin film resistors 16 (16a-16d), the pull-up resistors 17, and the current-limit resistors 18. Then, as shown in FIG. 2E, after removing the photoresist 30, the second TEOS layer 19 is formed for covering the thin film resistors 16, the pull-up resistors 17 and the current-limit resistors 18, for example. The second Al wires 20 are patterned and formed on the second TEOS layer 19, and the protection layer 21 is formed on the second TEOS layer for covering the second Al wires 20. In this way, the semiconductor device 1 is formed.

In the semiconductor device 1 according to the embodiment, the thin film resistors 16 having the resistances within the predetermined error range are formed in the first area N, in which the thickness of the photoresist 30 is approximately even in the state the photoresist 30 covers the resistor layer 22 formed on the first Al wire 14. The resistors having the resistances, which are allowable to be out of the predetermined error range, can be formed in the second area M. The second area M is adjacent to the first Al wire, 14, and the thickness of the photoresist 30 in the second area M is uneven due to the step height H between the first Al wire 14 and the BPSG layer 13. In the conventional semiconductor device, the second area M is a dead space without any resistor, and the resistors having resistances, which are allowable to be out of the predetermined error range, such as the pull-up resistors 17 and the current-limit resistors 18 are formed in another space. However, in the semiconductor device 1 according to the embodiment, additional space for the pull-up resistors 17 and the current-limit resistors 18 is not required. Therefore, the semiconductor device 1, in which the thin film resistors have the resistances within the predetermined error range, and the chip size is small, can be provided.

### Other Embodiments

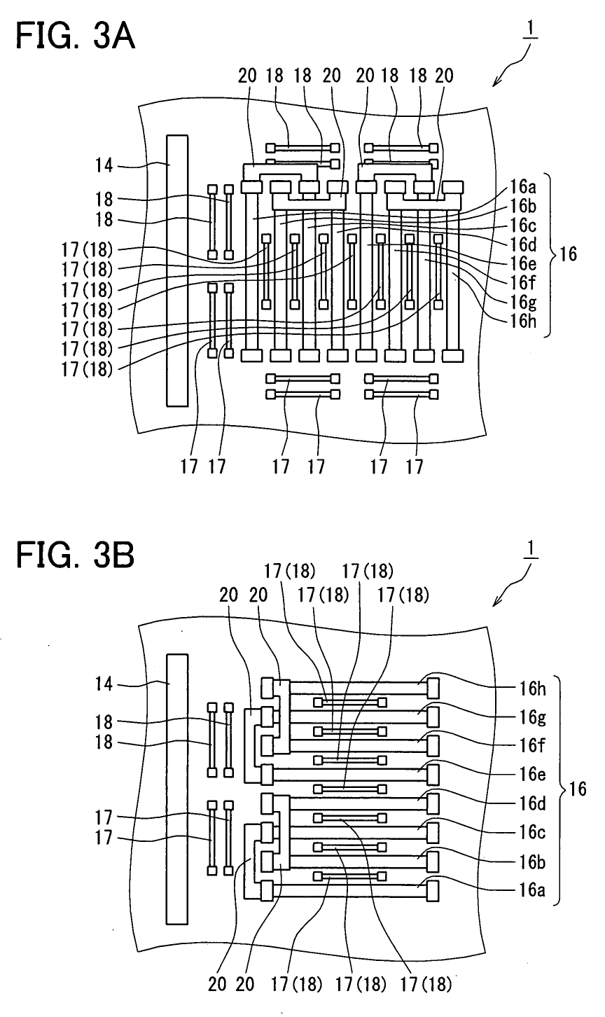

The resistors having resistances which are allowable to be out of the predetermined error range, such as the pull-up resistors 17 and the current-limit resistors 18, may be located not only in the area between the first Al wire 14 and the thin film resistors 16, but also adjacent to the thin film resistors 16. For example, as shown in FIG. 3A, the pull-up resistors 17 and the current-limit resistors 18 may be located in parallel adjacent to the thin film resistors 16 in a direction perpendicular to the thin film resistors 16, and may be located between the thin film resistors 16. Herewith, the pull-up resistors 17 and the current-limit resistors 18 can be arranged compactly.

The thin film resistors 16 are not limited to be arranged parallel to the first Al wire 14. For example, as shown in FIG. 3B, the thin film resistors 16 may be located so that the each of the thin film resistors 16 are parallel to each other in a direction perpendicular to the first Al wire 14, and are same distance from the first Al wire 14. Also in this case, the pull-up resistors 17 and the current-limit resistors 18 may be arranged between the thin film resistors 16. Therefore, the chip size of the semiconductor device 1 can be small.

Such changes and modifications are to be understood as being within the scope of the present invention as defined by the appended claims.

What is claimed is:

1. A semiconductor device comprising:
a semiconductor substrate;
a first wire disposed on the semiconductor substrate;
a first insulating layer disposed on the semiconductor substrate and the first wire;
a first thin film resistor having a first resistance within a predetermined error range; and
a second thin film resistor having a second resistance which is allowable to be out of the predetermined error range, wherein:
a surface of the first insulating layer includes a first area and a second area, in which the second area is located adjacent to the first wire; and
the first thin film resistor is disposed in the first area, and the second thin film resistor is disposed in the second area.

2. The semiconductor device according to claim 1, wherein:
the first area and second area are defined in such a manner that when a photoresist covers a resistor material film disposed on the surface of the first insulating layer, a thickness of the photoresist is approximately even in the first area, and the thickness of the photoresist is uneven in the second area due to a step height between the first wire and the surface of the semiconductor substrate; and
the resistor material film provides the first and second thin film resistors.

3. The semiconductor device according to claim 2, wherein:
the second thin film resistor is a pull-up resistor or a current-limit resistor.

4. A semiconductor device comprising:
a semiconductor substrate;
a first wire disposed on the semiconductor substrate;
a first insulating layer disposed on the semiconductor substrate and the first wire;
a first thin film resistor having a first resistance within a first error range; and
a second thin film resistor having a second resistance within a second error range, wherein:
the first error range is smaller than the second error range;
a surface of the first insulating layer includes a first area and a second area, in which the second area is located adjacent to the first wire; and
the first thin film resistor is disposed in the first area, and the second thin film resistor is disposed in the second area.

5. The semiconductor device according to claim 4, wherein:
the first area and second area are defined in such a manner that when a photoresist covers a resistor material film disposed on the surface of the first insulating layer, a thickness of the photoresist is approximately even in the first area, and the thickness of the photoresist is uneven in the second area due to a step height between the first wire and the surface of the semiconductor substrate; and
the resistor material film provides the first and second thin film resistors.

6. The semiconductor device according to claim 5, wherein:
the second thin film resistor is a pull-up resistor or a current-limit resistor.

7. The semiconductor device according to claim 6, wherein:
a width of the second area in a direction perpendicular to the first wire is approximately 100 μm.

8. The semiconductor device according to claim 7, further comprising:
a second insulating layer disposed on the first insulating layer, the first thin film resistor, and the second thin film resistor; and
a plurality of second wires disposed on the second insulating layer, wherein:
the first thin film resistor has a plurality of stripe-shaped thin film resistors arranged in parallel to each other at even intervals; and
each of the second wires are connected with two of the stripe-shaped thin film resistors.

9. The semiconductor device according to claim 8, wherein:
the plurality of stripe-shaped thin film resistors is arranged in parallel to the first wire.

10. The semiconductor device according to claim 8, wherein:
the plurality of stripe-shaped thin film resistors is arranged perpendicularly to the first wire.

11. The semiconductor device according to claim 8, wherein:
the semiconductor substrate has a semiconductor element, a field oxide layer, and a boron-phosphorous silicate glass layer;
the first wire and the plurality of the second wires are made of Al;
the first insulating layer and the second insulating layer are made of tetraethoxysilane; and
the first thin film resistor and the second thin film resistor are made of CrSi.

12. A method for manufacturing a semiconductor device comprising:
forming a first wire on a surface of a semiconductor substrate;
forming a first insulating layer on the semiconductor substrate and the first wire;
dividing a surface of the first insulating layer into a first area and a second area, in which the second area is located adjacent to the first wire;
forming a first thin film resistor having a first resistance within a first error range in the first area; and
forming a second thin film resistor having a second resistance within a second error range in the second area, wherein:
the first error range is smaller than the second error range;
the first area and the second area are defined in such a manner that when a photoresist covers a resistor material film arranged on the surface of the first insulating layer, a thickness of the photoresist is approximately even in the first area, and the thickness of the photoresist is uneven in the second area due to a step height between the first wire and the surface of the semiconductor substrate; and
the resistor material film provides the first and second thin film resistors.

13. The method for manufacturing a semiconductor device according to claim 12, wherein:
the second thin film resistor is a pull-up resistor or a current-limit resistor.

14. The method for manufacturing a semiconductor device according to claim 13, wherein:
a width of the second area in a direction perpendicular to the first wire is approximately 100 μm.

15. The method for manufacturing a semiconductor device according to claim 14, wherein:
the first thin film resistor has a plurality of stripe-shaped thin film resistors arranged in parallel to each other at even intervals, the method further comprising:
forming a second insulating layer on the first insulating layer, the first thin film resistor, and the second thin film resistor;
forming a plurality of second wires on the second insulating layer; and
connecting each of the second wires with two of the stripe-shaped thin film resistors.

16. The method for manufacturing a semiconductor device according to claim 15, wherein:
the plurality of stripe-shaped thin film resistors is arranged in parallel to the first wire.

17. The method for manufacturing a semiconductor device according to claim 15, wherein:
the plurality of stripe-shaped thin film resistors is arranged perpendicularly to the first wire.

18. The method for manufacturing a semiconductor device according to claim 15, wherein:
the semiconductor substrate has a semiconductor element, a field oxide layer, and a boron-phosphorous silicate glass layer;
the first wire and the plurality of the second wires are made of Al;
the first insulating layer and the second insulating layer are made of tetraethoxysilane; and
the first thin film resistor and the second thin film resistor are made of CrSi.
